(19) United States
(12) Patent Application Publication
(10) Pub. No.: US 2013/0337172 A1
(43) Pub. Date: Dec. 19, 2013

(54) REACTOR IN DEPOSITION DEVICE WITH MULTI-STAGED PURGING STRUCTURE

(71) Applicant: Synos Technology, Inc., Fremont, CA (US)

(72) Inventor: Sang In Lee, Sunnyvale, CA (US)

(73) Assignee: Synos Technology, Inc., Fremont, CA (US)

(21) Appl. No.: 13/904,825

(22) Filed: May 29, 2013

Related U.S. Application Data
(60) Provisional application No. 61/661,750, filed on Jun. 19, 2012.

(51) Int. Cl. C23C 16/455

(52) U.S. Cl. CPC C23C 16/455
USPC 427/255.5; 118/719

(57) ABSTRACT

Embodiments relate to a structure of reactors in a deposition device that enables efficient removal of excess material deposited on a substrate by using multiple-staged Venturi effect. In a reactor, constriction zones of different height are formed between injection chambers and an exhaust portion. As purge gas or precursor travels from injection chambers to the exhaust portion and passes the constriction zones, the pressure of the gas drops and the speed of the gas increase. Such changes in the pressure and speed facilitate removal of excess material deposited on the substrate.

### CROSS-REFERENCE TO RELATED APPLICATION

This application claims priority under 35 U.S.C. §119(e) to co-pending U.S. Provisional Patent Application No. 61/661,750, filed on Jun. 19, 2012, which is incorporated by reference herein in its entirety.

### BACKGROUND

1. Field of Art

The disclosure relates to depositing one or more layers of materials on a substrate by using atomic layer deposition (ALD) or other deposition methods, and more particularly to effectively removing excess material from the substrate.

2. Description of the Related Art

Various chemical processes are used to deposit one or more layers of material on a substrate. Such chemical processes include, among others, chemical vapor deposition (CVD), atomic layer deposition (ALD) and molecular layer deposition (MLD). CVD is the most common method for depositing a layer of material on a substrate. In CVD, reactive gas precursors are mixed and then delivered to a reaction chamber where a layer of material is deposited after the mixed gas comes into contact with the substrate.

ALD is another way of depositing material on a substrate. ALD uses the bonding force of a chemisorbed molecule that is different from the bonding force of a physisorbed molecule. In ALD, source precursor is adsorbed into the surface of a substrate and then purged with an inert gas. As a result, physisorbed molecules of the source precursor (bonded by the Van der Waals force) are desorbed from the substrate. However, chemisorbed molecules of the source precursor are covalently bonded, and hence, these molecules are strongly adsorbed in the substrate and not desorbed from the substrate. The chemisorbed molecules of the source precursor (adsorbed on the substrate) react with and/or are replaced by molecules of reactant precursor. Then, the excessive precursor or physisorbed molecules are removed by injecting the purge gas and/or pumping the chamber, obtaining a final atomic layer.

MLD is a thin film deposition method similar to ALD but in MLD, molecules are deposited onto the substrate as a unit to form polymeric films on a substrate. In MLD, a molecular fragment is deposited during each reaction cycle. The precursors for MLD have typically been homobifunctional reactants. MLD method is used generally for growing organic polymers such as polyamides on the substrate. The precursors for MLD and ALD may also be used to grow hybrid organic-inorganic polymers such as Alucone (i.e., aluminum alkoxide polymer having carbon-containing backbones obtained by reacting trimethylaluminum (TMA: Al(CH₃)₃) and ethylene glycol) or Zircone (hybrid organic-inorganic systems based on the reaction between zirconium precursor (such as zirconium t-butoxide Zr[OC(CH₃)₃)]₄, or tetrakis(dimethylamido)zieconium Zr[N(CH₃)₂]₄) with diol (such as ethylene glycol)).

During these deposition methods, precursors or other materials physisorbed on the substrate may be purged for subsequent processes. If excess precursors or other materials remain on the substrate after the purging process, the resulting layer may have undesirable characteristics. Hence, a scheme for effectively removing excess precursors or other materials from the surface of the substrate may be implemented for various deposition methods.

### SUMMARY

Embodiments relate to a reactor formed with multiple constriction zones that facilitate removal of excess material remaining on a substrate. The reactor is formed with a first chamber, a second chamber, a first constriction zone, a second constriction zone and an exhaust portion. The first chamber injects a first gas onto the substrate passing across the first chamber. The second chamber injects a second gas onto the substrate passing across the second chamber. The first constriction zone is configured to route the first gas from the first chamber to the second chamber over the substrate. The first constriction zone is formed between the first chamber and the second chamber. The first constriction zone is configured so that the pressure of the first gas in the first constriction zone is lower than the pressure of the first gas in the first chamber and the speed of the first gas in the first constriction zone is higher than the pressure of the first gas in the first chamber. The second constriction zone is configured to route at least the second gas from the second chamber to the exhaust portion over the substrate. The second constriction zone is formed between the second chamber and the exhaust portion. The pressure of the second gas in the second constriction zone is lower than the pressure of the second gas in the second chamber and the speed of the second gas in the second constriction zone is higher than speed of the second gas in the second chamber.

In one embodiment, the height of the first constriction zone is smaller than the width of the first chamber.

In one embodiment, the height of the second constriction zone is smaller than the height of the first constriction zone.

In one embodiment, the height of the second constriction zone is smaller than ⅔ of the width of the second chamber.

In one embodiment, the height of the second constriction zone is smaller than the width of the second chamber.

In one embodiment, the first gas is a purge gas and the second gas is a source precursor or a reactant precursor for performing atomic layer deposition (ALD) on the substrate.

In one embodiment, the purge gas includes Argon and the second gas includes one of TetraEthylMethylAminoHafnium (TEMAHf), Tetrakis(DiMethylAmido)Titanium (TDMAT), mixed alkylamido-cyclopentadienyl compounds of zirconium [(RCp)Zr(NMe₂)₃ (R═H, Me or Et)], Trimethyl(methylcyclopentadienyl)platinum (MeCpPtMe₃), and bis(ethylcyclopentadienyl)ruthenium [Ru(EtCp)₂].

In one embodiment, the second gas includes H₂O, H₂O₂, O₃, NO, O* radical, NH₂—NH₂, NH₃, N* radical, H₂, H* radical, C₂H₂, C* radical or F* radical.

In one embodiment, the reactor is further formed with a third chamber and a fourth chamber. The third chamber is configured to receive a third gas. The third constriction zone is configured to route the third gas from the third chamber to the first chamber over the substrate.

Embodiments also relate to a method of depositing material on a substrate using a reactor with multiple constriction zones. A relative movement is caused between a susceptor receiving a substrate and a reactor. A first gas is provided into a first chamber formed in the reactor, and injected onto the substrate passing across the first chamber. The first gas is routed from the first chamber to a second chamber of the reactor via a first constriction zone formed in the reactor over the substrate. A second gas is provided into a second chamber in the reactor and injected onto the substrate. The second gas is routed from the second chamber to an exhaust portion formed in the reactor over the substrate via a second constriction zone formed in the reactor.

### BRIEF DESCRIPTION OF DRAWINGS

FIG. 1 is a cross sectional diagram of a linear deposition device, according to one embodiment.

FIG. 2 is a perspective view of the linear deposition device of FIG. 1, according to one embodiment.

FIG. 3 is a perspective view of a rotating deposition device, according to one embodiment.

FIG. 4 is a perspective view of reactors in a deposition device, according to one embodiment.

FIG. 5A is a cross sectional diagram illustrating a reactor taken along line A-B of FIG. 4, according to one embodiment.

FIG. 5B is a bottom view of the reactor of FIG. 5A, according to one embodiment.

FIG. 5C is a cross sectional diagram illustrating a reactor, according to another embodiment.

FIG. 6 is a conceptual diagram describing the purge operation in the reactor of FIG. 5A, according to one embodiment.

FIG. 7 is a sectional diagram of a reactor with three constriction zones, according to another embodiment.

FIG. 8 is a sectional diagram of a symmetric reactor, according to another embodiment.

FIG. 9 is a flowchart for performing a deposition process, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to a structure of reactors in a deposition device that enables efficient removal of excess material (e.g., physisorbed precursor molecules) deposited on a substrate by using multiple constructions zones to cause multiple-staged Venturi effect. In a reactor, constriction zones of different heights are formed between injection chambers and an exhaust portion. As purge gas or precursor travels from injection chambers to the exhaust portion and passes the constriction zones, the pressure of the gas drops and the speed of the gas increase. Such changes in the pressure and speed facilitate removal of excess material deposited on the substrate. By providing multiple constriction zones, multi-staged Venturi effect is caused, resulting in more thorough removal of excess material from the substrate.

### Example Apparatus for Performing Deposition

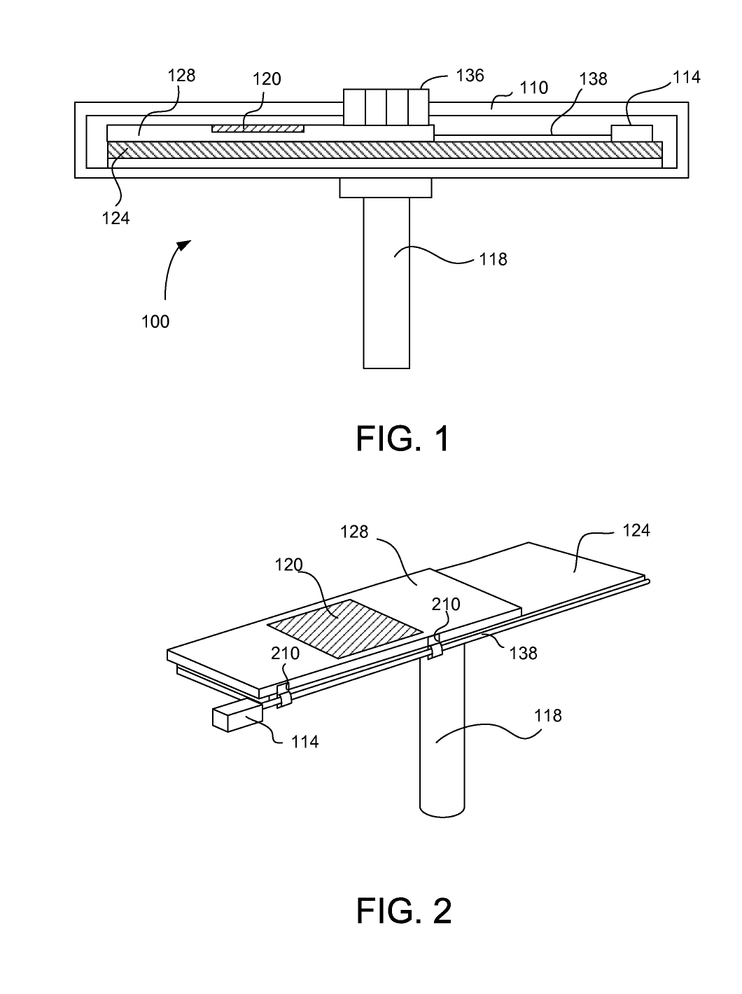

FIG. 1 is a cross sectional diagram of a linear deposition device 100, according to one embodiment. FIG. 2 is a perspective view of the linear deposition device 100 (without chamber walls to facilitate explanation), according to one embodiment. The linear deposition device 100 may include, among other components, a support pillar 118, the process chamber 110 and one or more reactors 136. The reactors 136 may include one or more of injectors and radical reactors for performing MLD, ALD and/or CVD. Each of the injectors injects source precursors, reactant precursors, purge gases or a combination of these materials onto the substrate 120. The gap between the injector and the substrate 120 may be 0.5 mm to 1.5 mm.

The process chamber enclosed by walls may be maintained in a vacuum state to prevent contaminants from affecting the deposition process. The process chamber 110 contains a susceptor 128 which receives a substrate 120. The susceptor 128 is placed on a support plate 124 for a sliding movement. The support plate 124 may include a temperature controller (e.g., a heater or a cooler) to control the temperature of the substrate 120. The linear deposition device 100 may also include lift pins (not shown) that facilitate loading of the substrate 120 onto the susceptor 128 or dismounting of the substrate 120 from the susceptor 128.

In one embodiment, the susceptor 128 is secured to brackets 210 that move across an extended bar 138 with screws formed thereon. The brackets 210 have corresponding screws formed in their holes receiving the extended bar 138. The extended bar 138 is secured to a spindle of a motor 114, and hence, the extended bar 138 rotates as the spindle of the motor 114 rotates. The rotation of the extended bar 138 causes the brackets 210 (and therefore the susceptor 128) to make a linear movement on the support plate 124. By controlling the speed and rotation direction of the motor 114, the speed and the direction of the linear movement of the susceptor 128 can be controlled. The use of a motor 114 and the extended bar 138 is merely an example of a mechanism for moving the susceptor 128. Various other ways of moving the susceptor 128 (e.g., use of gears and pinion or a linear motor at the bottom, top or side of the susceptor 128). Moreover, instead of moving the susceptor 128, the susceptor 128 may remain stationary and the reactors 136 may be moved.

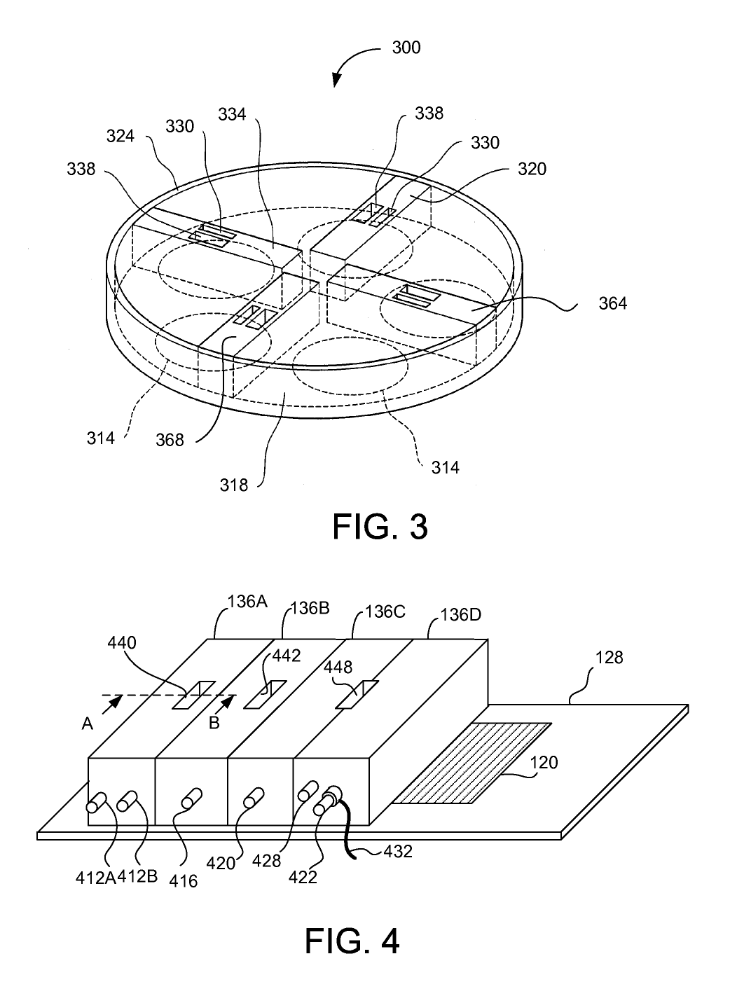

FIG. 3 is a perspective view of a rotating deposition device 300, according to one embodiment. Instead of using the linear deposition device 100 of FIG. 1, the rotating deposition device 300 may be used to perform the deposition process according to another embodiment. The rotating deposition device 300 may include, among other components, reactors 320, 334, 364, 368, a susceptor 318, and a container 324 enclosing these components. A reactor (e.g., 320) of the rotating deposition device 300 corresponds to a reactor 136 of the linear deposition device 100, as described above with reference to FIG. 1. The susceptor 318 secures the substrates 314 in place. The reactors 320, 334, 364, 368 may be placed with a gap of 0.5 mm to 1.5 mm from the substrates 314 and the susceptor 318. Either the susceptor 318 or the reactors 320, 334, 364, 368 rotate to subject the substrates 314 to different processes.

One or more of the reactors 320, 334, 364, 368 are connected to gas pipes (not shown) to provide source precursor, reactor precursor, purge gas and/or other materials. The materials provided by the gas pipes may be (i) injected onto the substrate 314 directly by the reactors 320, 334, 364, 368, (ii) after mixing in a chamber inside the reactors 320, 334, 364, 368, or (iii) after conversion into radicals by plasma generated within the reactors 320, 334, 364, 368. After the materials are injected onto the substrate 314, the redundant materials may be exhausted through outlets 330, 338. The interior of the rotating deposition device 300 may also be maintained in a vacuum state.

Although following example embodiments are described primarily with reference to the reactors 136 in the linear deposition device 100, the same principle and operation can be applied to the rotating deposition device 300 or other types of deposition device.

FIG. 4 is a perspective view of reactors 136A through 136D (collectively referred to as the “reactors 136”) in the deposition device 100 of FIG. 1, according to one embodiment. In FIG. 4, the reactors 136 are placed in tandem adjacent to each other. In other embodiments, the reactors 136 may be placed with a distance from each other. As the susceptor 128 mounting the substrate 120 moves from the left to the right or from the right to the left, the substrate 120 is sequentially injected with materials or radicals by the reactors 136 to form a deposition layer on the substrate 120. Instead of moving the substrate 120, the reactors 136 may move from the right to the left while injecting the source precursor materials or the radicals on the substrate 120.

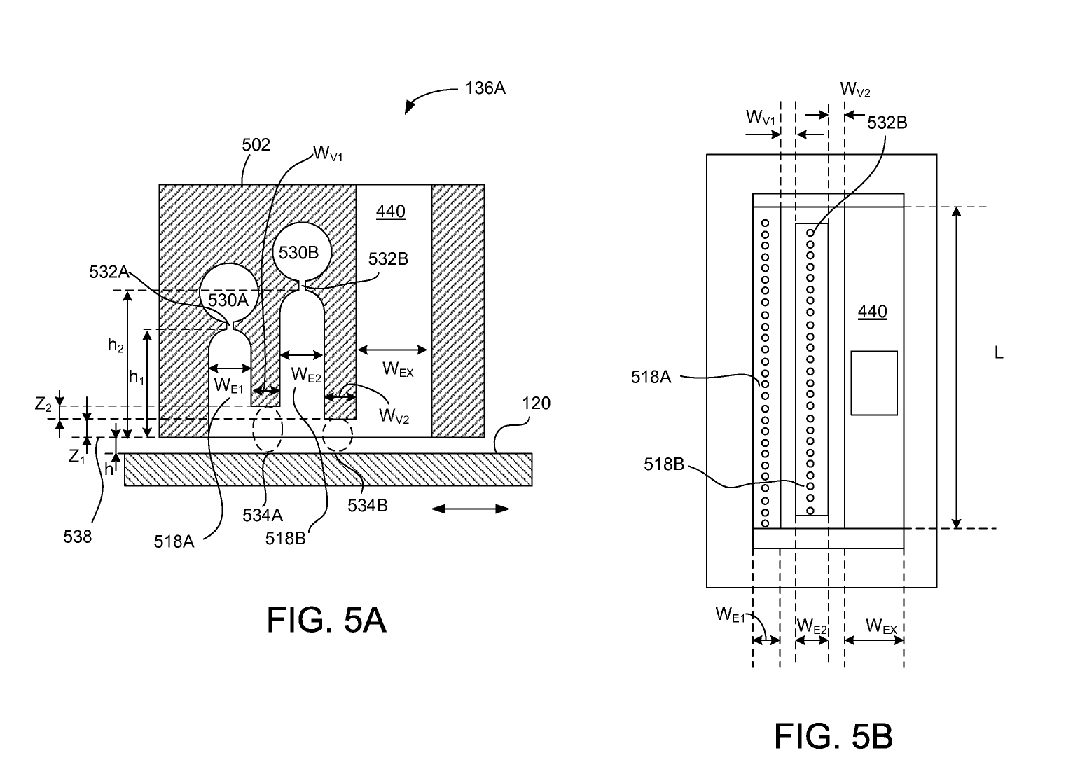

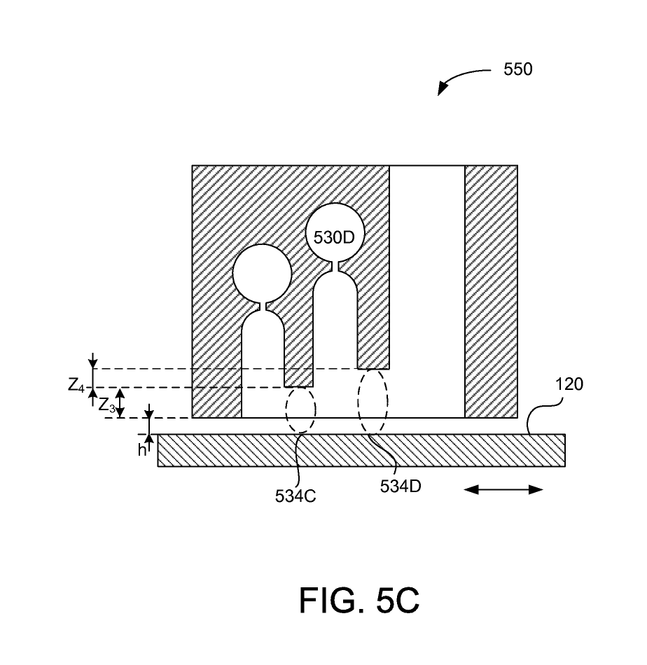

In one or more embodiments, the reactors 136A, 136B, 136C are gas injectors that inject precursor material, purge gas or a combination thereof onto the substrate 120. Each of the reactors 136A, 136B, 136C is connected to pipes 412A, 412B, 416, 420 to receive precursors, purge gas or a combination thereof from one or more sources. Valves and other pipes (refer to FIG. 5) may be installed between the pipes 412, 416, 420 and the sources to control the gas and the amount thereof provided to the gas injectors 136A, 136B, 136C. Excess precursor and purge gas molecules are exhausted via exhaust portions 440, 442, 448.

The reactor 136D is a radical injector that generates reactant radicals using plasma. The plasma an be generated using direct current (DC), DC pulse or radio frequency (RF) signal provided via cable 432 to an electrode 422 extending across the reactor 136D. The reactor 136D is connected to pipe 428 to receive reactant precursor (for example, N₂O or O₃ for generating O* radicals). In one embodiment, the body of the reactor 136D may be coupled to ground.

Excess source precursor, reactant precursor and purge gas molecules are exhausted via exhaust portions 440, 442, 448.

Reactor with Two-Staged Constriction Zones

FIG. 5A is a cross sectional diagram illustrating the reactor 136A taken along line A-B of FIG. 4, according to one embodiment. The injector 136A includes a body 502 formed with gas channels 530A, 530B, perforations (slits or holes) 532A, 532B, chambers 518A, 518B, constriction zones 534A, 534B, and an exhaust portion 440 (having a width of W_{EX}). The gas channel 530A is connected to the pipe 412A to convey purge gas into the chamber 518A via the perforations 532A. The gas channel 530B is connected to the pipe 412B to convey precursor gas into the chamber 518B via the perforations 532B. A region of the substrate 120 below the reaction chamber 518B comes into contact with the precursor via the chamber 518B and adsorbs source precursor molecules on its surface.

The remaining precursor (i.e., precursor remaining after part of the precursor is adsorbed on the substrate 120) passes through the constriction zone 534B and are discharged via the exhaust portion 440. After exposure of the substrate 120 to the precursor below the injection chamber 518B, excess precursor molecules (e.g., physisorbed precursor molecules) may remain on the surface of the substrate 120. As the precursor passes through the constriction zone 534B, Venturi effect causes the pressure of the precursor to drop and the speed of the precursor in the constriction zone 534B to increase. As a result, when a region of the substrate 120 moves below the constriction zone 534B, excess precursor on the region of the substrate 120 is at least partly removed by Venturi effect in the constriction zone 534B.

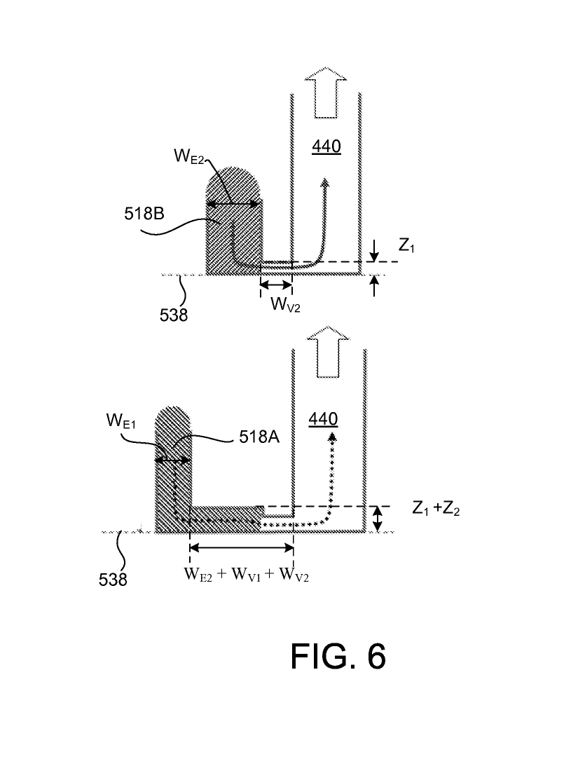

For more thorough removal of excess precursor (and other undesirable remnants on the substrate), purge gas is injected into the chamber 518A via the perforations 532A. The purge gas is then discharged through the exhaust portion 440 via the constriction zone 534A, below the chamber 518B and via the constriction zone 534B. As the purge gas passes the constriction zone 534A and the constriction zone 534B, Venturi effect causes the pressure of the purge gas to drop and the speed of the purge gas to increase. Venturi effect of the purge gas facilitates further removal of the excess precursor from the surface of the substrate 120. The purge gas passes through an extended virtual constriction zone spanning from the constriction zone 534A to constriction zone 534B, as described below in detail with reference to FIG. 6; and therefore, the purge gas in conjunction with the precursor gas passing below the constriction zone 534B effectively removes the excess precursor on the substrate. Hence, even precursors with high viscosity or low vapor pressure can be removed effectively by using the reactor 136A.

As illustrated in FIG. 5A, the constriction zone 534A has a height (Z₁+Z₂) that is shorter than height h₁ of the chamber 518A, and the constriction zone 534B has a height Z1 that is shorter than height h₂ of the chamber 518B. Further, the height of the constriction zone 534A from the bottom of the body 502 (indicated by line 538) to the ceiling of the constriction zone 534A is (Z₁+Z₂) and its width is Wᵥ₁. The height of the constriction zone 532B from the bottom of the body 502 to the ceiling of the constriction zone 532B is Z₁ and its width is Wᵥ₂. In one embodiment, W_{V2} is larger than W_{V1}.

FIG. 5B is a bottom view of the reactor 136A of FIG. 5A, according to one embodiment. The reactor 136A has a width of L. The chambers 518A, 518B have width of W_{E1} and W_{E2}, respectively. The purge gas in the chambers 518A passes through the constriction zone 534A, below the chamber 518B, and the constriction zone 534B into the exhaust portion 440. The precursor gas in the chamber 518B passes through the constriction zone 534B into the exhaust portion 440.

FIG. 5C is a cross sectional diagram illustrating a reactor 550 of FIG. 4, according to one embodiment. The reactor 550 is similar to the reactor 136A except that the reactor 550 is formed with a first constriction zone 534C and a second constriction zone 534D. The first constriction zone 534C has a height of Z₃ whereas the second constriction zone 534D has a height of (Z₃+Z₄) higher than the height Z₃ of the first constriction zone 534C. In other embodiments (not illustrated), the constriction zones may have the same height. If the sticking coefficient of the precursor injected from 530D is low or vapor pressure of the precursor injected from 530D is high, the height of the constriction zone 534D may be set to be the same or higher than the height of the constriction zone 534C.

In one embodiment, Argon gas is used as the purge gas injected through the chamber 518A and TetraEthylMethylAminoHafnium (TEMAHf) is used as precursor injected through the chamber 518B. TEMAHf may be heated to in the range of 50° C. to 100° C. in order to provide sufficient vapor pressure. Alternatively, one or more of Tetrakis(DiMethylAmido)Titanium (TDMAT), mixed alkylamido-cyclopentadienyl compounds of zirconium [(RCp)Zr(NMe₂)₃ (R═H, Me or Et)], Trimethyl(methylcyclopentadienyl)platinum (MeCpPtMe₃), and bis(ethylcyclopentadienyl)ruthenium [Ru(EtCp)₂] may be used as the precursor in lieu of or in addition to TEMAHf. Also, H₂O, H₂O₂, O₃, NO, O* radical, NH₂—NH₂, NH₃, N* radical, H₂, H* radical, C₂H₂, C* radical or F* radical may be used as the precursor injected through the chamber 518B.

FIG. 6 is a conceptual diagram for describing the purge operation in the reactor 136A of FIG. 5A, according to one embodiment. The precursor injected into the chamber 518B and passes constriction zone 534B into the exhaust portion 440. The height Z₁ of the constriction zone 534B is set to be smaller than the width W_{E2} of the chamber 518B. Since the precursor can be seen as flowing through a conduit with width W_{E2} into a conduit of width Z₂ (narrower than W_{E2}), Venturi effect causes the pressure of the precursor to drop and the speed of the precursor to increase in the constriction zone 534B. Hence, the flow of precursor in the constriction zone 534B at least partially removes the excess material (e.g., physisorbed precursor molecules) on the substrate 120, as a first stage of purging.

The constriction zone 534B also functions as a communication channel between the chamber 518B and the exhaust 440. The constriction zone 534B enables the precursor from the chamber 518B to the exhaust 440 to make a directional laminar flow without causing the precursor to diffuse randomly below the reactor 136A.

In one embodiment, height Z₁ of the constriction zone 534B is set to be smaller than ⅔ of the width W_{E2} of the chamber 518B to cause Venturi effect sufficient to remove physisorbed precursor molecules on the substrate 120.

The purge gas (e.g., Argon) travels across the constriction zone 532A, the chamber 518B and the constriction zone 534B to the exhaust portion 440. The height (Z₁+Z₂) of the constriction zone 534A is set to be smaller than the width W_{E1} of the chamber 518A. The purge gas traveling across the constriction zone 532A and the chamber 518B can be seen as passing from a conduit having a width of W_{E1} into a conduit having a height of (Z₁+Z₂) and a length of (W_{E1}+W_{V1}+W_{V2}). The flow of the purge gas from a wider conduit of W_{E1} width to a narrow height of (Z₁+Z₂) width causes Venturi effect, and hence, the speed of the purge gas increases and the pressure of the purge gas drops in the constriction zone 534A. Such Venturi effect results in purging by the purge gas in the constriction zone 534A that removes excess material from the substrate 120.

The purge gas then moves through the constriction zone 534B having a further reduced height of (Z₂+h) and a length W_{V2}. While the purge gas passes constriction zone 534B, purging is performed by Venturi effect of the purge gas due to further narrowing of passage in the constriction zone 534B. Hence, the speed of the purge gas further increases while the pressure of the purge gas further decreases as the purge gas travels through chamber 518A. Such Venturi effect of the purge gas in the constriction zone 534B further removes the excess material on the substrate 120. The removal of excess material due to the flow of the purge gas constitutes a second stage of purging.

In one embodiment, (Z₁+Z₂) of the constriction zone 534A is smaller than ⅔ of the width W_{E1} of the chamber 518A to cause Venturi effect sufficient to remove physisorbed precursor molecules on the substrate 120.

The purge gas and the precursor pass through the constriction zones 534A, 534B and remove excess materials on the surface of the substrate due to the Venturi effect. In addition, the purge gas may also remove or prevent re-adsorption of any byproduct generated by reaction in the reactor 136A. By promoting removal of excess precursor and byproduct, the properties of the layer formed by ALD, MLD or CVD can be enhanced.

Although embodiments described above with reference to FIGS. 5A through 6 inject purge gas into chamber 518A and precursor gas into chamber 518B, such arrangement is merely illustrative. Instead, a type of precursor gas (e.g., reactant precursor or source precursor) can be injected into chamber 518A and another type of precursor gas (e.g., source precursor or reactant precursor) can be injected into chamber 518B. Alternatively, a first source precursor (or a first reactant precursor) may be injected into chamber 518A and a second source precursor (or a second reactant precursor) may be injected into chamber 518B.

Reactor with Three-Staged Constriction Zones

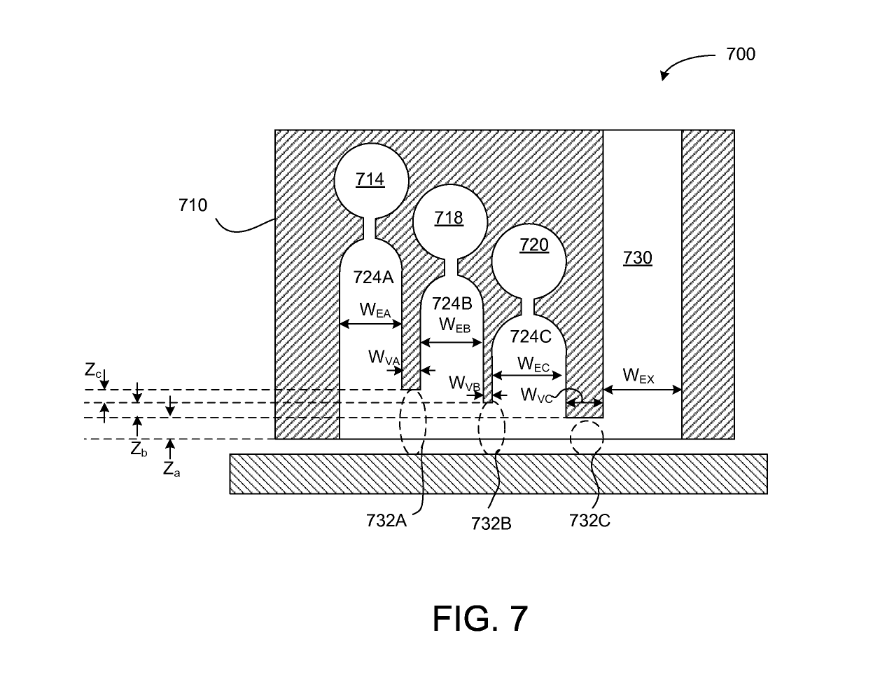

FIG. 7 is a sectional diagram of a reactor 700 with a three-staged constriction zones, according to another embodiment. The body 710 of the reactor 700 is formed with channels 714, 718, 720, chambers 724A, 724B, 724C, perforations connecting the channels to the chambers, an exhaust portion 730, and constriction zones 732A, 732B, 732C. Compared to the reactor 136A, the reactor 700 has an additional channel 714, chamber 724A and the constriction zone 732A.

Purge gas injected through the channel 714 fills the chamber 724A and then passes the constriction zone 732A, below the chamber 724B, the constriction zone 732B, below the chamber 724C, and the constriction zone 732C into the exhaust portion 730. The constriction zone 724A has a height of (Zₐ+Z_{b}+Z_{c}) from the bottom of the reactor 700 and a width of W_{VA}. The constriction zone 724B has a height of (Zₐ+Z_{b}) from the bottom of the reactor 700 and a width of W_{VB}. The constriction zone 724C has a height of Zₐ from the bottom of the reactor 700 and a width of W_{VC}.

In one embodiment, the height (Zₐ+Z_{b}+Z_{c}) is smaller than the width W_{EA} of the chamber 724A, and preferably, the height (Zₐ+Z_{b}+Z_{c}) is smaller than ⅔ of the width W_{EA}. The height (Zₐ+Z_{b}) is smaller than the width W_{EB} of the chamber 724B, and preferably, the height (Zₐ+Z_{b}) is smaller than ⅔ of the width W_{EB}. The height Zₐ is smaller than the width W_{EC} of the chamber 724C, and preferably, the height Zₐ is smaller than ⅔ of the width W_{EC}. In one embodiment, Z_{c} may have a value less than zero. That is the height of the constriction zone 732A may be lower than the height of the constriction zone 732B.

The reactor 700 may remove the precursor more efficiently than the reactor 136A since an additional stage of purge gas is used to purge the precursor from the surface of the substrate. The principle of removing excess precursor and byproducts using the gas injected via the chambers 724A through 724C of the reactor 700 is identical to that of the reactor 136A, and therefore, the detailed description thereof is omitted herein for the sake of brevity.

### Alternative Embodiments

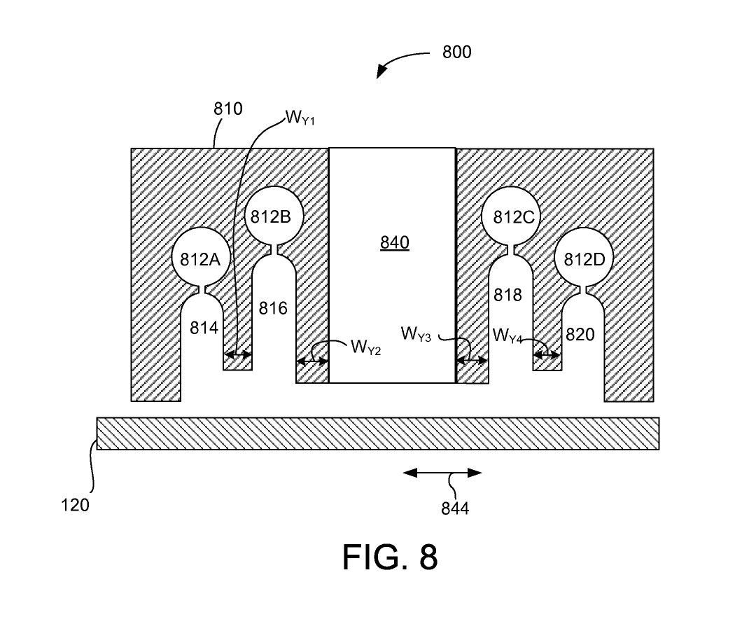

FIG. 8 is a sectional diagram of a reactor 800 with a symmetric structure, according to another embodiment. The reactor has a body 810 formed with channels 812A, 812B, 812C, 812D, chambers 814, 816, 818, 820, constriction zones (with widths of W_{Y1}, W_{Y2}, W_{Y3}, W_{Y4}) and perforations connecting the channels and the chambers.

In one embodiment, different precursors are injected via the channels 812B and 812C. For example, TEMAHf (TetraEthylMethylAminoHafnium) is injected via the channel 812B and 3DMAS (Trimimethylaminosilane: SiH[(CH₃)₂N]₃) is injected via channel 812C. Argon gas may be used as purge gas and is injected into via channels 812A and 812D.

Each precursor may use Argon as a carrier gas that is bubbled into a canister storing the precursor. For TEMAHf, the precursor may be heated to a temperature range of 50° C. to 100° C. to create sufficient vapor pressure. The substrate may move in one direction or in both directions, as shown by arrow 844.

The first precursor is TEMAHf that fills the chamber 816 with carrier gas such as Argon and then discharged to the exhaust portion 840 via the second constriction zone with width W_{Y2}. Purge gas is injected into the chamber 814, passed through the first constriction zone (with width W_{Y1}), below the chamber 816, the second constriction zone and is then discharged through the exhaust portion 840.

Similarly, another precursor such as 3DMAS fills the chamber 818 with carrier gas such as Argon, and is then discharged to the exhaust portion 840 via the third constriction zone (with width W_{Y3}). Simultaneously, purge gas fills the chamber 820, passes through the fourth constriction zone (with width W_{Y4}), below the chamber 818, the third constriction zone and is then discharged via the exhaust portion 840.

Therefore, as the substrate moves from the left to the right or from the right to the left, the substrate is exposed to TEMAHf and 3DMAS molecules, enabling formation of Hf—Si mixed layer by an ALD process. In another embodiment, the same precursor (e.g., TEMAHf or 3DMAS) is injected via the channels 812B and 812C. In this case, the substrate undergoes injection, adsorption and removal of the precursor per each cycle of the substrate movement to the left or the right.

In another embodiment, only one of the chambers 812B, 812C is used whereas the remaining chambers are used for injecting the purge gas. Such configuration is especially advantageous when the precursor is sticky and removal of excess precursor is difficult. By using three stages of purge gas, the excess precursor can be removed more thoroughly and effectively.

### Method of Depositing Material Using Multi-Staged Constriction Zones

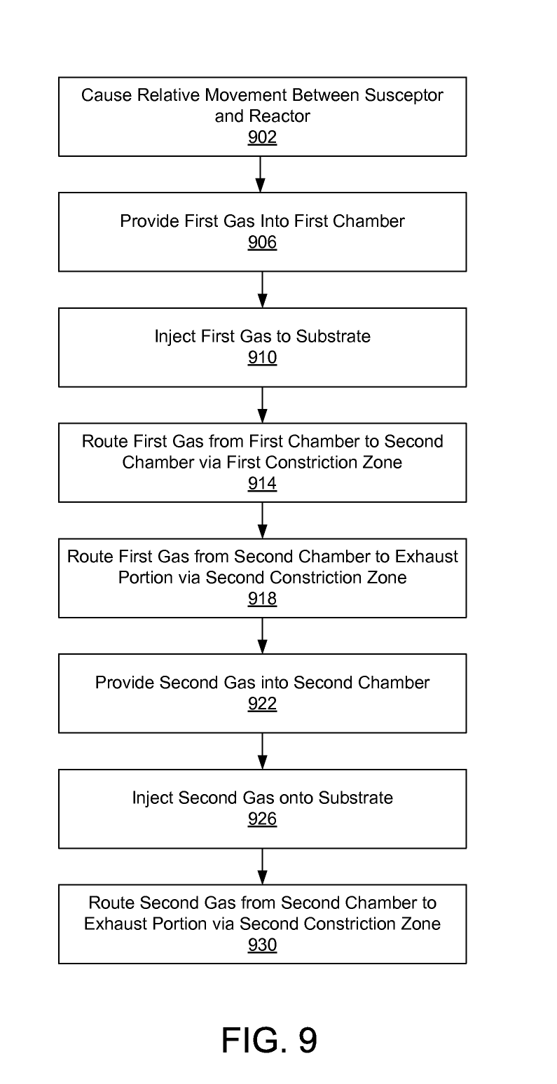

FIG. 9 is a flowchart for performing a deposition process, according to one embodiment. First, a relative movement between a susceptor receiving one or more substrates and a reactor is caused 902. The relative movement may be linear or circular.

A first gas is provided 906 to a first chamber 518A formed in the reactor. The first gas may be injected into the first chamber 518A, for example, channel 530A and perforations 532A. In one embodiment, the first gas is a purge gas.

The first gas is then injected 910 from the first chamber 518A onto the one or more substrates passing across the first chamber 518A.

The first gas from the first chamber 518A is routed 914 to a second chamber 518B formed in the reactor over the one or more substrates via a first constriction zone 534A formed in the reactor. The pressure of the first gas in the first constriction zone 534A is lower than the pressure of the first gas in the first chamber 518A. The speed of the first gas in the first constriction zone 534A is higher than the pressure of the first gas in the first chamber 518A.

The first gas is routed 918 from the second chamber 518B to an exhaust portion 440 formed in the reactor over the one or more substrates via a second constriction zone 534B formed in the reactor. The pressure of the first gas in the second constriction zone 534B is lower than the pressure of the first gas in the first constriction zone 534A. The speed of the first gas in the second constriction zone 534B is higher than the pressure of the first gas in the first constriction zone 534B.

A second gas is provided 922 into the second chamber 518B. The second gas may be a precursor for performing atomic layer deposition (ALD) on the substrates.

The second gas is injected 926 onto the substrate passing across the second chamber 518B. The second gas is routed 930 from the second chamber 518B to the exhaust portion 440 over the substrate via the second constriction zone 534B. The pressure of the second gas in the second constriction zone 534B is lower than the pressure of the second gas in the second constriction zone 534B. The speed of the second gas in the second constriction zone 534B is higher than the pressure of the second gas in the second chamber 518B.

The process as illustrated in FIG. 9 is merely illustrative. Various modifications may be made. For example, the second gas may be provided to the second chamber 518B before or at the same time that the first gas is provided to the first chamber 518A. Further, a third gas may be provided to a third chamber and routed via an additional constriction zone and through the first, second constriction zones 534A, 534B to the exhaust portion 440.

Although the present invention has been described above with respect to several embodiments, various modifications can be made within the scope of the present invention. Accordingly, the disclosure of the present invention is intended to be illustrative, but not limiting.

1. A deposition device for depositing material on a substrate, comprising:
a susceptor configured to receive one or more substrates; and
a reactor formed with:
a first chamber configured to inject a first gas onto the one or more substrates passing across the first chamber;
a second chamber configured to inject a second gas onto the one or more substrates passing across the second chamber;
a first constriction zone configured to route the first gas from the first chamber to the second chamber over the one or more substrates, the first constriction zone formed between the first chamber and the second chamber, the first constriction zone configured so that a pressure of the first gas in the first constriction zone is lower than a pressure of the first gas in the first chamber and a speed of the first gas in the first constriction zone is higher than a speed of the first gas in the first chamber;
an exhaust portion configured to discharge from the reactor the first gas and the second gas remaining after exposure to the one or more substrates; and
a second constriction zone configured to route the first gas and the second gas from the second chamber to the exhaust portion over the one or more substrates, the second constriction zone formed between the second chamber and the exhaust portion, the second constriction zone configured so that a pressure of the second gas in the second constriction zone is lower than a pressure of the second gas in the second chamber and a speed of the second gas in the second constriction zone is higher than a speed of the second gas in the second chamber.

2. The depositing device of claim 1, wherein a height of the first constriction zone is smaller than a width of the first chamber.

3. The deposition device of claim 1, wherein a height of the second constriction zone is smaller than a height of the first constriction zone.

4. The deposition device of claim 1, wherein a height of the second constriction zone is smaller than a width of the second chamber.

5. The deposition device of claim 4, wherein the height of the second constriction zone is smaller than ⅔ of the width of the second chamber.

6. The deposition device of claim 1, wherein the first gas is a purge gas and the second gas is a source precursor or a reactant precursor for performing atomic layer deposition (ALD) on the one or more substrates.

7. The deposition device of claim 6, wherein the purge gas comprises Argon and the second gas comprises one of TetraEthylMethylAminoHafnium (TEMAHf), Tetrakis(DiMethylAmido)Titanium (TDMAT), mixed alkylamido-cyclopentadienyl compounds of zirconium [(RCp)Zr(NMe₂)₃ (R═H, Me or Et)], Trimethyl(methylcyclopentadienyl)platinum (MeCpPtMe₃), and bis(ethylcyclopentadienyl)ruthenium [Ru(EtCp)₂].

8. The deposition device of claim 6, wherein the second gas comprises one of H₂O, H₂O₂, O₃, NO, O* radical, NH₂—NH₂, NH₃, N* radical, H₂, H* radical, C₂H₂, C* radical or F* radical.

9. The deposition device of claim 1, wherein the reactor is further formed with:
a third chamber configured to inject a third gas onto the one or more substrates, and
a third constriction zone configured to route the third gas from the third chamber to the first chamber over the one or more substrates.

10. The deposition device of claim 1, further comprising a mechanism configured to cause relative movement between the reactor body and the susceptor.

11. A method of depositing material on a substrate, comprising:
causing a relative movement between a susceptor receiving one or more substrates and a reactor;
providing a first gas into a first chamber formed in the reactor;
injecting the first gas onto the one or more substrates passing across the first chamber;
routing the first gas from the first chamber to a second chamber formed in the reactor over the one or more substrates via a first constriction zone formed in the reactor, a pressure of the first gas in the first constriction zone lower than a pressure of the first gas in the first chamber and a speed of the first gas in the first constriction zone higher than a speed of the first gas in the first chamber;
routing the first gas from the second chamber to an exhaust portion formed in the reactor over the one or more substrates via a second constriction zone formed in the reactor;
providing a second gas into the second chamber;
injecting the second gas onto the one or more substrates passing across the second chamber; and
routing the second gas from the second chamber to the exhaust portion over the one or more substrates via the second constriction zone, a pressure of the second gas in the second constriction zone lower than a pressure of the second gas in the second chamber and a speed of the second gas in the second constriction zone higher than a speed of the second gas in the second chamber.

12. The method of claim 11, wherein a pressure of the second gas in the second constriction zone is lower than a pressure of the second gas in the second chamber and a speed of the second gas in the second constriction zone is higher than a speed of the second gas in the second chamber.

13. The method of claim 11, wherein a height of the first constriction zone is smaller than a width of the first chamber.

14. The method of claim 11, wherein a height of the second constriction zone is smaller than a height of the first constriction zone.

15. The method of claim 11, wherein a height of the second constriction zone is smaller than a width of the second chamber.

16. The method of claim 15, wherein the height of the first constriction zone is smaller than ⅔ of the width of the first chamber.

17. The method of claim 11, wherein the first gas is a purge gas and the second gas is a source precursor or a reactant precursor for performing atomic layer deposition (ALD) on the one or more substrates.

18. The method of claim 17, wherein the purge gas comprises Argon and the second gas comprises one of TetraEthylMethylAminoHafnium (TEMAHf), Tetrakis(DiMethylAmido)Titanium (TDMAT), mixed alkylamido-cyclopentadienyl compounds of zirconium [(RCp)Zr(NMe₂)₃ (R═H, Me or Et)], Trimethyl(methylcyclopentadienyl)platinum (MeCpPtMe₃), and bis(ethylcyclopentadienyl)ruthenium [Ru(EtCp)₂].

19. The method of claim 17, wherein the second gas comprises one of H₂O, H₂O₂, O₃, NO, O* radical, NH₂—NH₂, NH₃, N* radical, H₂, H* radical, C₂H₂, C* radical or F* radical.

20. The method of claim 11, further comprising:
providing a third gas into a third chamber;
injecting the third gas onto the one or more substrates passing across the third chamber; and
routing the third gas from the third chamber to the first chamber via a third constriction zone over the one or more substrates.
